(19) United States
(12) Patent Application Publication
(10) Pub. No.: US 2014/0085825 A1
(43) Pub. Date: Mar. 27, 2014

(54) ELECTRONIC DEVICE AND HEAT CONDUCTION ELEMENT THEREOF

(71) Applicants: INVENTEC (PUDONG) TECHNOLOGY CORPORATION, (US); INVENTEC CORPORATION, Taipei (TW)

(72) Inventors: Feng-Ku Wang, Taipei (TW); Yi-Lun Cheng, Taipei (TW); Chih-Kai Yang, Taipei (TW)

(73) Assignees: INVENTEC CORPORATION, Taipei (TW); INVENTEC (PUDONG) TECHNOLOGY CORPORATION, Shanghai (CN)

(21) Appl. No.: 13/793,229

(22) Filed: Mar. 11, 2013

(30) Foreign Application Priority Data
Sep. 27, 2012 (CN) 201210370038.9

(51) Int. Cl. H05K 7/20; F28F 3/00

(52) U.S. Cl. CPC H05K 7/2039; F28F 3/00
USPC 361/704; 165/185

(57) ABSTRACT

A heat conduction element comprises a pressing portion and extending portions. A pressing side of the pressing portion is in thermal contact with a heat generating element. Each of the extending portions has a first end connected to the pressing portion and a second end away from the pressing portion. Each of the extending portions has a first surface facing the direction same as that of the pressing side and an oppositely disposed second surface. Each of the second ends has a fixing portion. At least one slot is formed between each of the extending portions and the pressing portion. The slot penetrates the first surface and the second surface. The shortest straight distance between each of the fixing portions and the pressing portion is smaller than or equal to the length extended from the first end to the second end of the extending portion.

### CROSS-REFERENCE TO RELATED APPLICATIONS

This non-provisional application claims priority under 35 U.S.C. §119(a) on Patent Application No(s). 201210370038.9 filed in China on Sep. 27, 2012, the entire contents of which are hereby incorporated by reference.

### BACKGROUND

1. Technical Field

The present disclosure relates to an electronic device and more particularly to an electronic device having a heat conduction element.

2. Related Art

In the recent years, the development trend for electronic devices is slim and compact in size, light in weight and high calculation speed. However, the computing elements in the electronic devices operating at high calculation speed generate large amount of heat, so that the temperatures of the computing elements increase speedily. As a result, the computing elements will crash easily and even get damaged. Therefore, it is highly demanded in the industry to look for solutions to speedily dissipate the heat generated by the computing element in the slim and compact space.

Among various heat dissipation methods, one technique is to use a heat pipe to dissipate heat. However, if the heat pipe is directly in contact with a computing element which is at high temperature, the heat pipe will be easily over-heated and unable to work properly. Therefore, a heat conduction element for transferring heat is disposed between the heat pipe and the computing element, and is directly fixed on the computing element. However, the amount of force applied in fixing the heat conduction element on the computing element is not easy to control and may easily cause damage to the computing element.

### SUMMARY

An electronic device of the present disclosure comprises a base, a heat generating element and a heat conduction element. The base has a plurality of fixing areas. The heat generating element is disposed on the base. The fixing areas are disposed around the heat generating element. The heat conduction element comprises a pressing portion and a plurality of extending portions. The pressing portion has a pressing side. The pressing side of the pressing portion is in thermal contact with the heat generating element. Each of the extending portions has a first end and a second end. The first end of each of the extending portions is connected to the pressing portion. The second end of each of the extending portions is disposed away from the pressing portion. Each of the extending portions has a first surface facing the direction same as that of the pressing side and a second surface opposite to the first surface. The second end of each of the extending portions has a fixing portion. At least one slot is formed between each of the extending portions and the pressing portion. The slot penetrates the first surface and the second surface. At least part of the slot is disposed between the pressing portion and the fixing portion of each of the extending portions. The shortest straight distance between each of the fixing portions and the pressing portion is smaller than or equal to the length extended from the first end to the second end of the extending portion. The fixing portions of the heat conduction element are disposed on the fixing areas. The extending portions can deform elastically, so that the pressing portion is capable of pressing against the heat generating element.

The present disclosure further provides a heat conduction element disposed on the base and in thermal contact with the heat generating element. The heat conduction element comprises a pressing portion and a plurality of extending portions. The pressing portion has a pressing side for thermal contacting with the heat generating element. Each of the extending portions has a first end and a second end. The first end of each of the extending portions is connected to the pressing portion. The second end of each of the extending portions is disposed away from the pressing portion. Each of the extending portions has a first surface facing the direction same as that of the pressing side and a second surface opposite to the first surface. The second end of each of the extending portions has a fixing portion. At least one slot is formed between each of the extending portions and the pressing portion. The slot penetrates the first surface and the second surface. At least part of the slot is disposed between the pressing portion and the fixing portion of each of the extending portions. Each of the fixing portions is suitable for being disposed on each of the fixing areas. The shortest straight distance between each of the fixing portions and the pressing portion is smaller than or equal to the length extended from the first end to the second end of the extending portion.

### BRIEF DESCRIPTION OF THE DRAWINGS

The present disclosure will become more fully understood from the detailed description given herein below for illustration only, and thus are not limitative of the present disclosure, and wherein:

FIG. 1A is an exploded perspective view of an electronic device according to an embodiment of the disclosure;

FIG. 1B is a perspective view of the electronic device according to an embodiment of the disclosure;

FIG. 1C is a sectional view of the electronic device according to an embodiment of the disclosure;

FIG. 1D is a sectional view of the electronic device according to an embodiment of the disclosure;

FIG. 2A is a perspective view of a heat conduction element according to another embodiment of the disclosure;

FIG. 2B is a perspective view of the heat conduction element according to another embodiment of the disclosure;

FIG. 2C is a perspective view of the heat conduction element according to another embodiment of the disclosure;

FIG. 3A is an exploded perspective view of the electronic device according to an embodiment of the disclosure;

FIG. 3B is a perspective view of the electronic device according to an embodiment of the disclosure;

FIG. 3C is a sectional view of the electronic device according to an embodiment of the disclosure; and

FIG. 3D is a sectional view of the electronic device according to an embodiment of the disclosure.

### DETAILED DESCRIPTION

The detailed characteristics and advantages of the disclosure are described in the following embodiments in details, the techniques of the disclosure can be easily understood and embodied by a person of average skill in the art, and the related objects and advantages of the disclosure can be easily understood by a person of average skill in the art by referring to the contents, the claims and the accompanying drawings disclosed in the specifications.

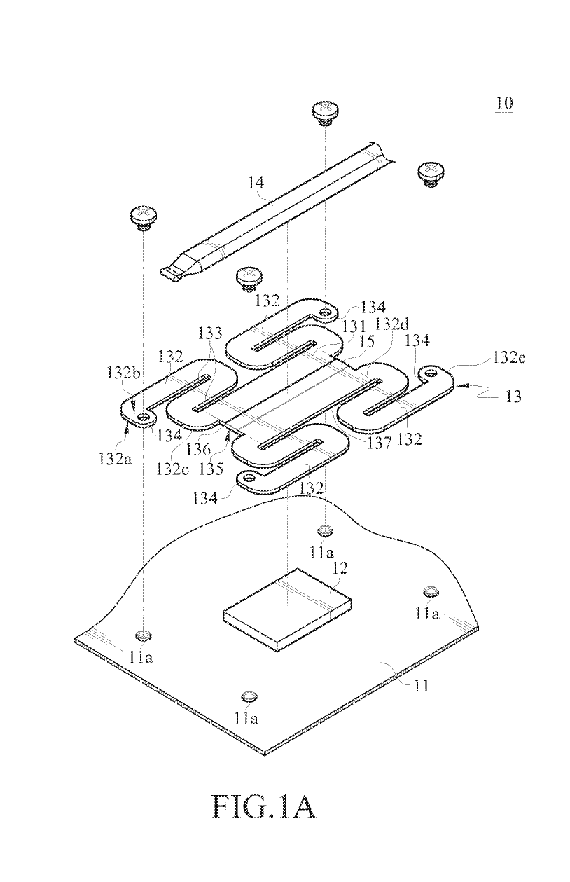

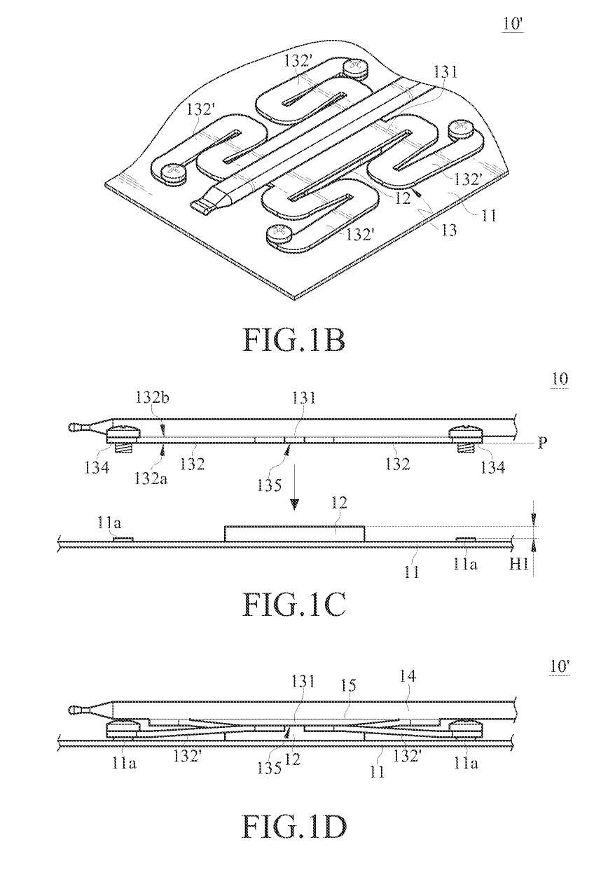

Please refer to FIG. 1A. FIG. 1A is an exploded view of an electronic device 10 according to an embodiment of the disclosure. The electronic device 10 can be a personal computer, a laptop or other electronic products. The electronic device 10 of the present disclosure comprises a base 11, a heat generating element 12 and a heat conduction element 13. The base 11 has a plurality of fixing areas 11a. The heat generating element 12 is disposed on the base 11. The fixing areas 11 a are disposed around the heat generating element 12. The heat conduction element 13 comprises a pressing portion 131 and a plurality of extending portions 132.

The heat conduction element 13 of the electronic device 10 is disposed on the base 11. The heat conduction element 13 can be in thermal contact with the heat generating element 12. The pressing portion 131 has a pressing side 135. The pressing side 135 of the pressing portion 131 is in thermal contact with the heat generating element 12. Each of the extending portions 132 has a first end 132d and a second end 132e. The first end 132d of each of the extending portions 132 is connected to the pressing portion 131. The second end 132e of each of the extending portions 132 is disposed a distance from the pressing portion 131. In this embodiment, the heat conduction element 13 has four of the extending portions 132. However, in some embodiments, the heat conduction element 13 has other quantity of the extending portions 132, for examples two, three or more than four. Each of the extending portions 132 has a first surface 132a and a second surface 132b. The first surfaces 132a and the pressing side 135 are facing the same direction. The second surfaces 132b are opposite to the first surfaces 132a. At least one slot 133 is formed between each of the extending portions 132 and the pressing portion 131. As shown in FIG. 1A, at least one of the slots 133 is formed by an edge 132c of each of the extending portions 132 extending inwardly. In this embodiment and some embodiments, each of the extending portions 132 has two of the slots 133; but the amount of the slots should not be construed as a limitation to the present disclosure. The slots 133 penetrate the extending portion from the first surface 132a to the second surface 132b. The second end 132e of each of the extending portions 132 has a fixing portion 134. In this embodiment, the slots 133 are disposed between the pressing portion 131 and the fixing portion 134 of each of the extending portions 132. In some embodiments, at least part of each of the slots 133 is between the pressing portion 131 and the fixing portion 134. In this embodiment, the shortest straight distance between each of the fixing portions 134 and the pressing portion 131 is smaller than the length extended from the first end 132d to the second end 132e of the extending portion 132; but in some embodiments, the shortest straight distance is equal to such length. Each of the fixing portions 134 of the heat conduction element 13 is disposed on each of the fixing areas 11a of the base 11.

Furthermore, in this embodiment, the electronic device 10 further comprises a heat pipe 14. The heat pipe 14 is adhered on the heat conduction element 13 by a heat conduction colloid 15. In some embodiments, the heat pipe 14 can also be disposed on the heat conduction element 13 by other means. The pressing portion 131 of the heat conduction element 13 has short edges 136 and long edges 137. In this embodiment, the extending portions 132 are extended from the short edges 136 of the pressing portion 131. The slots 133 are separated between the extending portion 132 and the pressing portion 131. The slot 133 nearest to the fixing portion 134 can be an L-shape. The two slots 133 are shifted in a way that the extending portion 132 is in a curve shape like an S.

Please refer to FIG. 1B. FIG. 1B is an electronic device 10′ according to an embodiment of the disclosure. When the heat conduction element 13 is disposed on the base 11, elastic force is provided by the elastically deformed extending portions 132′ for pressing the pressing portion 131 against the heat generating element 12. The stiffness of the extending portions 132′ is reduced, and the flexibility of the extending portions 132′ is enhanced by the slots 133 shown in FIG. 1A, so that when the heat conduction element 13 is fixed on the base 11, the damage to the heat generating element 12 due to too much pressing force being applying on the heat generating element 12 is prevented.

Please refer to FIG. 1C. FIG. 1C is a sectional view of the electronic device 10 according to an embodiment of the disclosure. As shown in FIG. 1C, before the heat conduction element 13 is disposed on the fixing areas 11a of the base 11, the pressing portion 131, the extending portions 132 and the fixing portions 134 can be on a same plane P. In some embodiments, the pressing portion 131 and the fixing portions 134 can be on different planes respectively. In this embodiment, relatively to the base 11, the height of the heat generating element 12 is higher than the height of the fixing areas 11a. The difference of height H1 is the difference of height between the heat generating element 12 and the fixing areas 11a. In some embodiments, the height of the heat generating element 12 can be equal to or less than the height of the fixing areas 11a.

Please refer to FIG. 1D. FIG. 1D is a sectional view of the electronic device 10′ according to an embodiment of the disclosure. In this embodiment, the heat generating element 12 is higher than the fixing areas 11a. Before the heat conduction element 13 is disposed on the base 11, the pressing portion 131, the extending portions 132′ and the fixing portions 134 are on a same plane P. Therefore, after the heat conduction element 13 is fixed to the base 11, the extending portions 132′ deforms elastically. Elastic force can be provided by the elastically deformed extending portions 132′ for pressing the pressing side 135 of the pressing portion 131 against the heat generating element 12. Thereby, the heat generated by the heat generating element 12 can be transferred to the heat conduction colloid 15 via the pressing portion 131 of the heat conduction element 13, the heat is transferred to the heat pipe 14, and then the heat pipe 14 dissipates the heat.

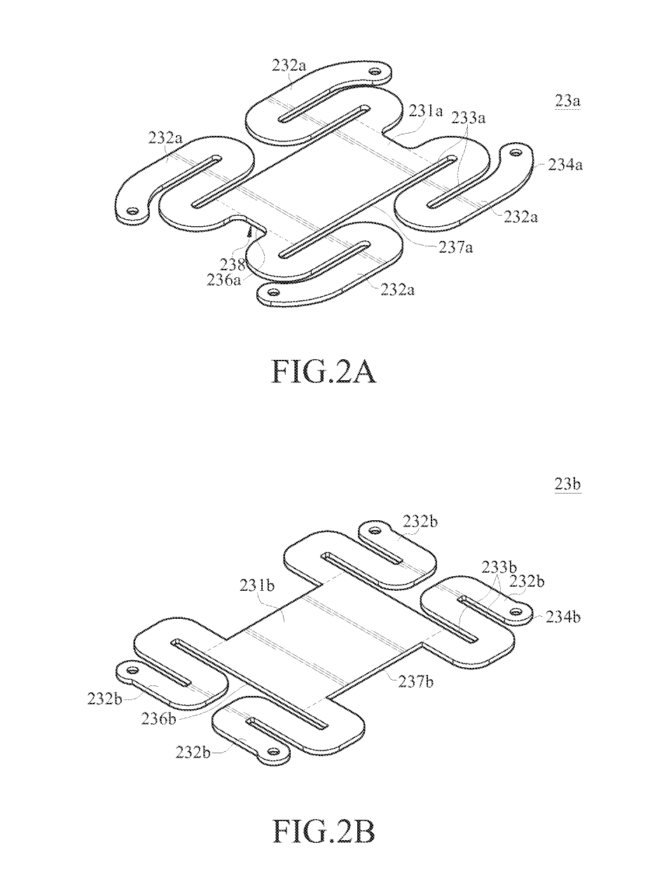

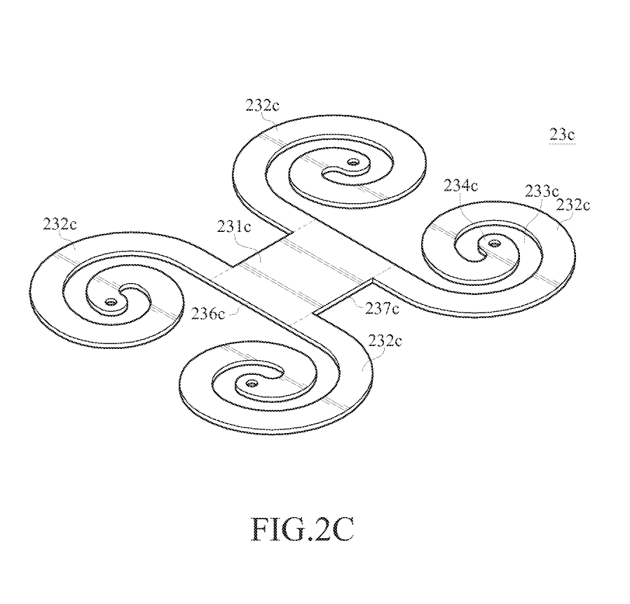

Please refer to FIG. 2A. FIG. 2A is a heat conduction element 23a according to another embodiment of the disclosure. In this embodiment, a pressing portion 231a of the heat conduction element 23a has two short edges 236a and two long edges 237a. In this embodiment, extending portions 232a are extended from the short edges 236a of the pressing portion 231a. Two slots 233a are separated between the extending portion 232a and the pressing portion 231a. The slot 233a nearest to a fixing portion 234a can be a curve shape with the same width. The two slots 233a are shifted in a way that the extending portion 232a is in a curve shape like an S. Furthermore, a round corner 238 is formed between each of the extending portions 232a and the short edge 236a to prevent stress concentration from forming between the extending portion 232a and the short edge 236a.

Please refer to FIG. 2B. FIG. 2B is a heat conduction element 23b according to another embodiment of the disclosure. In this embodiment, a pressing portion 231b of the heat conduction element 23b has two short edges 236b and two long edges 237b. In this embodiment, extending portions 232b are extended from the long edges 237b of the pressing portion 231b. Two slots 233b are separated between the extending portion 232b and the pressing portion 231b. The slot 233b nearest to a fixing portion 234b can be a strip shape with the same width. The two slots 233b are shifted in a way that the extending portion 232b is in a curve shape like an S.

Please refer to FIG. 2C. FIG. 2C is a heat conduction element 23c according to another embodiment of the disclosure. In this embodiment, a pressing portion 231c of the heat conduction element 23c has two short edges 236c and two long edges 237c. In this embodiment, extending portions 232c are extended from the long edges 237c of the pressing portion 231c. In some embodiments, the extending portions 232c can be extended from the short edges 236c of the pressing portion 231c. Each of the slots 233c is a curved strip with the same width. Each of the slots 233c is disposed around a fixing portion 234c so that the extending portions 232c are in spiral shape. Therefore, part of each of the slots 233c is disposed between the pressing portion 231c and the fixing portion 234c of each of the extending portions 232c.

The heat conduction elements 23a, 23b and 23c in FIGS. 2A to 2C can be used in the electronic devices 10 and 10′ in FIGS. 1A to 1D. Furthermore, the extending portions 232a, 232b and 232c of the heat conduction elements 23a, 23b and 23c can be used in the following electronic devices 30 and 30′.

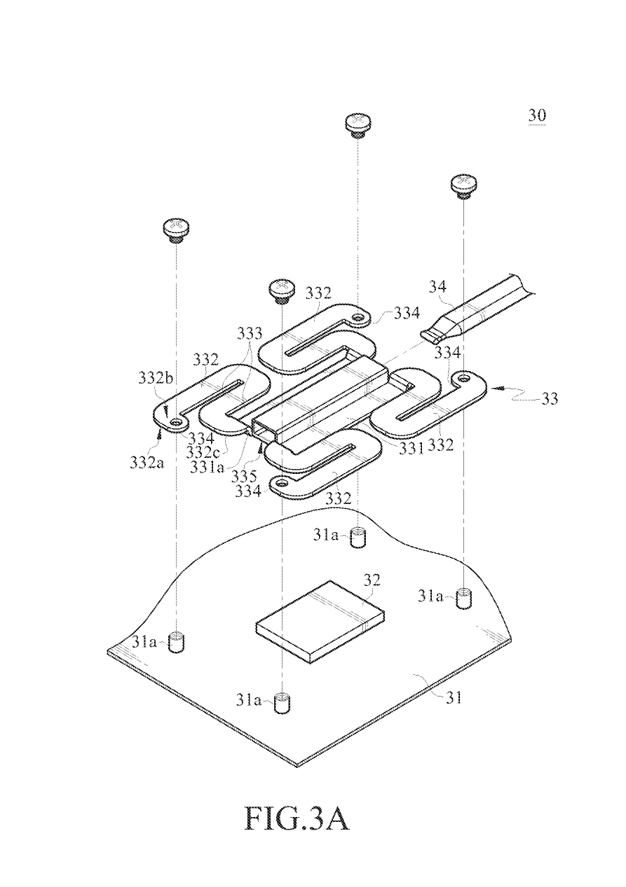

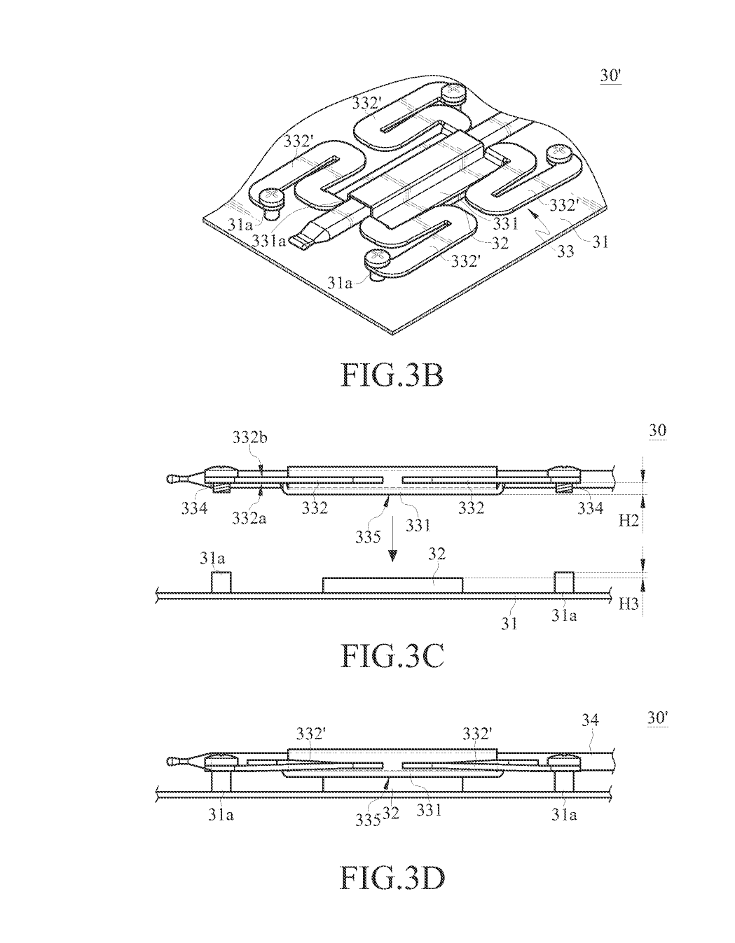

Please refer to FIG. 3A. FIG. 3A is an exploded view of the electronic device 30 according to an embodiment of the disclosure. The electronic device 30 of the disclosure comprises a base 31, a heat generating element 32 and a heat conduction element 33. The base 31 has a plurality of fixing areas 31a. The heat generating element 32 is disposed on the base 31. The fixing areas 31a are disposed around the heat generating element 32. The heat conduction element 33 comprises a pressing portion 331 and a plurality of extending portions 332.

The heat conduction element 33 of the electronic device 30 is disposed on the base 31. The heat conduction element 33 can be in thermal contact with the heat generating element 32. The pressing portion 331 has a pressing side 335. The pressing side 335 of the pressing portion 331 is in thermal contact with the heat generating element 32. The extending portions 332 extend from the pressing portion 331. In this embodiment, the heat conduction element 33 has four of the extending portions 332. However, in some embodiments, the heat conduction element 33 can also have other quantity of the extending portions 332, for examples two, three or more than four. Each of the extending portions 332 has a first surface 332a and a second surface 332b. The first surfaces 332a and the pressing side 335 face the same direction. The second surfaces 332b are opposite to the first surfaces 332a. At least one slot 333 is formed by extending an edge 332c of each of the extending portions 332 inwardly. In this embodiment, each of the extending portions 332 has two of the slots 333; but it should not be construed as a limitation to the present disclosure. The slots 333 penetrate the first surface 332a and the second surface 332b. An end of each of the extending portions 332 away from the pressing portion 331 has a fixing portion 334. In this embodiment, the slots 333 are disposed between the pressing portion 331 and the fixing portion 334 of each of the extending portions 332. In some embodiments, at least part of each of the slots 333 is disposed between the pressing portion 331 and the fixing portion 334. Each of the fixing portions 334 of the heat conduction element 33 is disposed on each of the fixing areas 31a of the base 31.

Furthermore, in this embodiment, the pressing portion 331 further has a through hole 331a. The electronic device 30 further comprises a heat pipe 34. The heat pipe 34 can be disposed inside the through hole 331a of the pressing portion 331 in order to dispose the heat pipe 34 in the heat conduction element 33. In some embodiments, the heat pipe 34 can also be disposed on the heat conduction element 33 by other means.

Please refer to FIG. 3B. FIG. 3B is a perspective view of an electronic device 30′ according to an embodiment of the disclosure. When the heat conduction element 33 is disposed on the base 31, elastic force can be provided by the elastically deformed extending portions 332′ for pressing the pressing portion 331 against the heat generating element 32. The stiffness of the extending portions 332′ can be reduced and the flexibility of the extending portions 332′ can be enhanced by the slots 333, so that when the heat conduction element 33 is fixed on the base 31, damage to the heat generating element 32 due to too much pressing force applying to the heat generating element 32 is prevented.

Please refer to FIG. 3C. FIG. 3C is a sectional view of the electronic device 30 according to an embodiment of the disclosure. As shown in FIG. 3C, before the heat conduction element 33 is disposed on the base 31, the pressing portion 331 and the fixing portions 334 are on different planes, respectively. The difference of height H2 is the difference of height between the pressing portion 331 and the fixing portions 334. In this embodiment, the pressing portion 331 is nearer to the base 31 than the fixing portions 334. In this embodiment, relatively to the base 31, the height of the heat generating element 32 is lower than the height of the fixing areas 31a. The difference of height H3 is the difference of height between the heat generating element 32 and the fixing areas 31a. In this embodiment, the difference of height H2 is bigger than the difference of height H3.

Please refer to FIG. 3D. FIG. 3D is a sectional view of the electronic device 30′ according to an embodiment of the disclosure. In this embodiment, the heat generating element 32 is lower than the fixing areas 31a; before the heat conduction element 33 is disposed on the base 31, the difference of height H2 is bigger than the difference of height H3; therefore, after the heat conduction element 33 is disposed on the base 31, the extending portions 332′ deform elastically. Elastic force can be provided by the elastically deformed extending portions 332′ for pressing the pressing portion 331 against the heat generating element 32. Thereby, the heat generated by the heat generating element 32 can be transferred to the heat pipe 34 via the pressing portion 331 of the heat conduction element 33 for the heat pipe 34 to dissipate the heat.

According to the electronic device and its heat conduction element of the present disclosure, elastic force can be provided by the elastically deformed extending portions for pressing the pressing portion of the heat conduction element against the heat generating element. The heat generated by the heat generating element can be transferred to the heat pipe via the pressing portion of the heat conduction element, and then the heat pipe dissipates the heat. The stiffness of the extending portions can be reduced and the flexibility of the extending portions can be enhanced by the slots, so that while the heat conduction element is fixed on the base, the damage to the heat generating element due to too much pressing force being applied to the heat generating element is prevented.

Note that the specifications relating to the above embodiments should be construed as exemplary rather than as limitative of the present invention, with many variations and modifications being readily attainable by a person of average skill in the art without departing from the spirit or scope thereof as defined by the appended claims and their legal equivalents.

What is claimed is:

1. An electronic device, comprising:
a base having a plurality of fixing areas;
a heat generating element disposed on the base, the fixing areas being disposed around the heat generating element; and
a heat conduction element, comprising:
a pressing portion having a pressing side, the pressing side of the pressing portion being in thermal contact with the heat generating element; and
a plurality of extending portions, each of the extending portions having a first end and a second end, the first end of each of the extending portions being connected to the pressing portion, the second end of each of the extending portions being disposed away from the pressing portion, each of the extending portions having a first surface facing the direction same as that of the pressing side and a second surface opposite to the first surface, the second end of each of the extending portions having a fixing portion, at least one slot being formed between each of the extending portions and the pressing portion, the slot penetrating the first surface and the second surface, at least part of the slot being disposed between the pressing portion and the fixing portion of each of the extending portions, the shortest straight distance between each of the fixing portions and the pressing portion being smaller than or equal to the length extended from the first end to the second end of the extending portion;
wherein the fixing portions of the heat conduction element are disposed on the fixing areas, the extending portions is adapted to deform elastically to provide elastic force for the pressing portion to press against the heat generating element.

2. The electronic device as claimed in claim 1, wherein the electronic device further comprises a heat pipe, the heat pipe is adhered on the heat conduction element by a heat conduction colloid.

3. The electronic device as claimed in claim 1, wherein the electronic device further comprises a heat pipe inserted in the pressing portion.

4. The electronic device as claimed in claim 1, wherein the slot is disposed around the fixing portion.

5. The electronic device as claimed in claim 1, wherein relatively to the base, the height of the heat generating element is higher than the height of the fixing areas.

6. The electronic device as claimed in claim 1, wherein relatively to the base, the height of the heat generating element is lower than the height of the fixing areas.

7. A heat conduction element for disposing on a base and in thermal contact with a heat generating element, the heat conduction element comprising:
a pressing portion having a pressing side for thermal contacting with the heat generating element; and
a plurality of extending portions, each of the extending portions having a first end and a second end, the first end of each of the extending portions being connected to the pressing portion, the second end of each of the extending portions being disposed away from the pressing portion, each of the extending portions having a first surface facing the direction same as that of the pressing side and a second surface opposite to the first surface, the second end of each of the extending portions having a fixing portion, at least one slot being formed between each of the extending portions and the pressing portion, the slot penetrating the first surface and the second surface, at least part of the slot being disposed between the pressing portion and the fixing portion of each of the extending portions, each of the fixing portions is adapted to be disposed on each of the fixing areas, the shortest straight distance between each of the fixing portions and the pressing portion being smaller than or equal to the length extended from the first end to the second end of the extending portion.

8. The heat conduction element as claimed in claim 7, wherein the slot is disposed around the fixing portion.

9. The heat conduction element as claimed in claim 7, wherein the pressing portion, the extending portions and the fixing portions are on a same plane.

10. The heat conduction element as claimed in claim 7, wherein the pressing portion and the fixing portions are on different planes.
